(19) United States
(12) Patent Application Publication
(10) Pub. No.: US 2009/0314332 A1
(43) Pub. Date: Dec. 24, 2009

(54) HIGH EFFICIENCY SOLAR CELL

(76) Inventors: Allen M. Barnett, Landenberg, PA (US); David Emil Carlson, Williamsburg, VA (US); William Alan Doolittle, Hampton, GA (US); Christiana Beatrice Honsberg, Tempe, AZ (US); Douglas Andrew Kirkpatrick, Great Falls, VA (US)

Correspondence Address: POTTER ANDERSON & CORROON LLP;ATTN: JANET E. REED, PH.D., P.O. BOX 951, WILMINGTON, DE, 19899-0951, US

(21) Appl. No.: 12/358,894

(22) Filed: Jan. 23, 2009

Related U.S. Application Data
(63) Continuation of application No. PCT/US2007/016667, filed on Jul. 25, 2007.
(60) Provisional application No. 60/833,994, filed on Jul. 28, 2006.

(51) Int. Cl. H01L 31/052

(52) U.S. Cl. 136/246

(57) ABSTRACT

This invention relates to a high efficiency solar cell with a novel architecture. In one embodiment, the solar cell is comprised of a high energy gap cell stack and a dichroic mirror. The high energy gap cell stack is exposed to solar light before there is any splitting of the solar light into spectral components. Each cell in the high energy gap cell stack absorbs the light with photons of energy greater than or equal to its energy gap, i.e., the blue-green to ultraviolet portion of the solar light. Each cell in the high energy gap cell stack is transparent to and transmits light with photons of energy less than its energy gap. Spectral splitting is then performed by means of the dichroic mirror on the remaining light, i.e., the light transmitted by the high energy gap cell stack.

### CROSS-REFERENCE TO RELATED APPLICATION

This application is a Continuation of International Application Number PCT/US2007/016667, filed Jul. 25, 2007, which claims priority to U.S. Provisional application No. 60/833,994, filed Jul. 28, 2006, which is incorporated in its entirely.

This invention was made with Government support under Agreement W911NF-05-9-0005 awarded by the Government. The Government has certain rights in the invention.

The invention claimed herein was made pursuant to the Articles of Collaboration for the 50% Efficient Solar Cells Consortium formed pursuant to the Defense Advanced Research Projects Agency (DARPA) award to the University of Delaware Oct. 1, 2005, W911NF-05-9-0005.

### FIELD OF THE INVENTION

This invention relates to a high efficiency solar cell suitable for use in both mobile and stationary applications.

### BACKGROUND OF THE INVENTION

Solar cell development has been in progress for over fifty years. One-junction silicon solar cells have received much attention over that period and are used in terrestrial photovoltaic applications. However, a one-junction silicon solar cell captures less than half of the theoretical potential for solar energy conversion with the best laboratory solar cells currently providing only about 24.7% efficiency. This limits the application of such cells.

High performance photovoltaic systems are required for both economic and technical reasons. The cost of electricity can be halved by doubling the efficiency of the solar cell. Many applications do not have the area required to provide the needed power using current solar cells.

Two types of solar cell architecture have been proposed for more efficient solar cells. One is a lateral architecture. An optical dispersion element is used to split the solar spectrum into its wavelength components. Separate solar cells are placed under each wavelength band and the cells are chosen so that they provide good efficiency for light of that wavelength band. Another architecture is a vertical one in which individual solar cells with different energy gaps are arranged in a stack. These are commonly referred to as cascade, tandem or multiple junction cells The solar light is passed through the stack.

There is a need for the development of high efficiency solar cells and an architecture that enables the achievement of such cells.

### SUMMARY OF THE INVENTION

This invention provides a high efficiency solar cell comprising a high energy gap cell (HEGC) stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack.

The solar cell further comprises one or more spectral beam splitters upon which the light transmitted by the HEGC stack impinges, wherein the one or more spectral beam splitters split the light transmitted by the HEGC stack into two or more spectral components.

In one aspect, this invention provides a high efficiency solar cell, comprising:
(a) a high energy gap cell (HEGC) stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack; and
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy ≧E_{g}^{m} and one component of light with photons of energy <E_{g}^{m} and wherein one of these components is reflected by the dichroic mirror and one is transmitted by the dichroic mirror.

In another aspect, this invention also provides a high efficiency solar cell, comprising:
(a) a high energy gap cell (HEGC) stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack,
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy ≧E_{g}^{m} and one component of light with photons of energy <E_{g}^{m} and wherein one of these components is reflected by the dichroic mirror and one is transmitted by the dichroic mirror;
(c) a mid energy gap cell (MEGC) stack that contains one or more cells with different energy gaps arranged vertically in descending order of their energy gaps with the first cell having the largest energy gap of the one or more cells in the MEGC stack, the MEGC stack being positioned so that the component of light with photons of energy ≧E_{g}^{m} impinges upon the surface of the first cell in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap; and
(d) a low energy gap cell (LEGC) stack that contains one or more cells with different energy gaps arranged vertically in descending order of their energy gaps with the first cell having the largest energy gap of the one or more cells in the LEGC stack, the LEGC stack being positioned so that the component of light with photons of energy <E_{g}^{m} impinges upon the surface of the first cell in the LEGC stack, wherein the -energy gap of each cell in the LEGC stack is <E_{g}^{m} and wherein the one or more cells in the LEGC stack each absorb light with photons of energy greater than or equal to their energy gap and are transparent to and transmit light with photons of energy less than their energy gap.

Preferably, E_{g}^{m} is about equal to the energy gap of the cell with the lowest energy gap of all the cells to which the component of light with photons of energy ≧E_{g}^{m} is directed.

The invention also provides a method for converting solar light into electrical power, the method comprising:
(a) positioning a high energy gap cell (HEGC) stack so that solar light impinges onto the surface of the first cell of the HEGC stack before there is any splitting of the solar light into spectral components, wherein the HEGC stack contains one or more cells with different energy gaps arranged vertically in descending order of their energy gaps with the first cell having the largest energy gap of the one or more cells in the HEGC stack, wherein the energy gap of each cell in the HEGC stack is ≧E_{g}^{h}, and wherein the one or more cells in the HEGC stack each absorb light with photons of energy greater than or equal to their energy gap and are transparent to and transmit light with photons of energy less than their energy gap thereby providing light transmitted by the HEGC stack;
(b) spatially separating the light transmitted by the HEGC stack into two spectral components of light, one component of light with photons of energy ≧E_{g}^{m} and one component of light with photons of energy <E_{g}^{m};
(c) positioning a mid energy gap cell (MEGC) stack so that the component of light with photons of energy ≧E_{g}^{m} impinges upon the surface of the first cell in the MEGC stack, wherein the MEGC stack contains one or more cells with different energy gaps arranged vertically in descending order of their energy gaps with the first cell having the largest energy gap of the one or more cells in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap; and
(d) positioning a low energy gap cell (LEGC) stack so that the component of light with photons of energy <E_{g}^{m} impinges upon the surface of the first cell in the LEGC stack, wherein the LEGC stack contains one or more cells with different energy gaps arranged vertically in descending order of their energy gaps with the first cell having the largest energy gap of the one or more cells cells in the LEGC stack, and wherein the one or more cells in the LEGC stack each absorb light with photons of energy greater than or equal to their energy gap and are transparent to and transmit light with photons of energy less than their energy gap.

### BRIEF DESCRIPTION OF THE FIGURES

FIG. 1 shows a schematic drawing of a cell stack.

FIG. 2 illustrates an embodiment of the solar cell with the “HEGC stack-dichroic mirror” architecture with a dichroic mirror that reflects light with photons of energy ≧E_{g}^{m} and transmits light with photons of energy <E_{g}^{m}.

FIG. 3 illustrates an embodiment of the solar cell with the “HEGC stack-dichroic mirror-MEGC stack” architecture with a dichroic mirror that reflects light with photons of energy ≧E_{g}^{m} and transmits light with photons of energy <E_{g}^{m}.

FIG. 4 illustrates an embodiment of the solar cell with the “HEGC stack-dichroic mirror-LEGC stack” architecture with a dichroic mirror that reflects light with photons of energy ≧E_{g}^{m} and transmits light with photons of energy <E_{g}^{m}.

FIG. 5 illustrates an embodiment of the solar cell with the “HEGC stack-dichroic mirror-MEGC stack-LEGC stack” architecture with a dichroic mirror that reflects light with photons of energy ≧E_{g}^{m} and transmits light with photons of energy <E_{g}^{m}.

FIG. 6 illustrates still another embodiment of the solar cell with the “HEGC stack-dichroic mirror-MEGC stack-LEGC stack” architecture with a dichroic mirror that reflects light with photons of energy ≧E_{g}^{m} and transmits light with photons of energy <E_{g}^{m}.

FIG. 7 illustrates an embodiment of the solar cell with the “HEGC stack-dichroic mirror-MEGC stack-LEGC stack” architecture with a dichroic mirror that transmits light with photons of energy ≧E_{g}^{m} and reflects light with photons of energy <E_{g}^{m}.

### DETAILED DESCRIPTION OF THE PREFERRED EMBODIMENTS

The instant invention provides a high efficiency solar cell with efficiency in excess of 30% and, preferably, up to and surpassing 50%.

In one embodiment, the solar cell is comprised of a high energy gap cell and a dichroic mirror to split the light transmitted by the high energy gap cell. In the novel solar cell architecture of the invention, the exposure of a high energy gap cell to the solar light before there is any splitting of the solar light into spectral components by a dispersion device plays a key role in enabling the achievement of a high efficiency solar cell and in providing various embodiments of the solar cell. This novel architecture provides efficient use of all portions of the solar spectrum in a manner that enables a practical high efficiency solar cell. The high energy cell absorbs the higher energy photons of energy ≧E_{g}^{h}, i.e., the blue-green to ultraviolet portion of the solar light, and converts that energy into electricity. The high energy cell is transparent to and transmits the photons of energy <E_{g}^{h}. Spectral splitting of the remaining light, i.e., the light transmitted by the high energy gap cell, is then performed by means of one or more spectral beam splitters. The spectral beam splitter can be a dichroic mirror, one or more prisms, one or more lenses, filters or any other optical splitter that will split the light into spectral components. Preferably, the spectral beam splitter is a dichroic mirror. Since the blue-green to ultraviolet light has been absorbed by the high energy gap cell before the spectral splitting, requirements for the dichroic mirror are relaxed. Therefore improved and less costly splitting of the remaining light can be achieved. Requirements on the cells used to absorb the remaining light and convert that energy into electricity are also relaxed. As a result a practical, high efficiency solar cell can be achieved.

The dichroic mirror operating at E_{g}^{m} is positioned so that the light transmitted by the high energy gap cell impinges upon the dichroic mirror. The so-called “cold” dichroic mirror reflects light with photons of energy ≧E_{g}^{m} and transmits light with photons of energy <E_{g}^{m}. The so-called “hot” dichroic mirror transmits light with photons of energy ≧E_{g}^{m} and reflects light with photons of energy <E_{g}^{m}. At the present stage of development of the two types of dichroic mirrors, the “cold” dichroic mirror is preferred. The dichroic mirror can be planar or curved. The light reflected by and transmitted by the dichroic mirror can then be absorbed by other cells and the energy converted into electricity.

In another embodiment, the high energy gap cell upon which the solar light impinges is one of two or more high energy gap cells with different energy gaps all of which are ≧E_{g}^{h}. The cells are arranged vertically in a HEGC stack in descending order of their energy gaps with the first cell having the largest energy gap. Again, exposing the first cell in the HEGC stack to the solar light before there is any splitting of the solar light into spectral components by a spectral beam splitter plays a key role in enabling the achievement of a high efficiency solar cell and in providing various embodiments of the solar cell. The first cell absorbs photons of energy greater than or equal to its energy gap and is transparent to and transmits photons of energy less than its energy gap. The second cell in the stack has a lower energy gap than the first cell and absorbs photons of energy greater than or equal to its energy gap and is transparent to and transmits photons of energy less than its energy gap. Similarly with any other cells present in the stack. In this embodiment, the dichroic mirror operating at E_{g}^{m} is positioned so that the light transmitted by the HEGC stack impinges upon the dichroic mirror. Again, the light reflected by and transmitted by the dichroic mirror can then be absorbed by other cells and the energy converted into electricity. The description of a HEGC stack that contains one or more cells with different energy gaps arranged vertically in descending order of their energy gaps with the first cell having the largest energy gap of the one or more cells in the HEGC stack cells, wherein solar light impinges upon the surface of the first cell in the HEGC stack, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap encompasses both of the above described embodiments, that having only one high energy gap cell and that having more than one high energy gap cell. These solar cells are herein referred to as solar cells with the “HEGC stack-dichroic mirror” architecture.

“Cell” is used herein to describe the individual cells that are contained in the various stacks and that are generally referred to as solar cells. The term “solar cell” is used herein to describe the complete device.

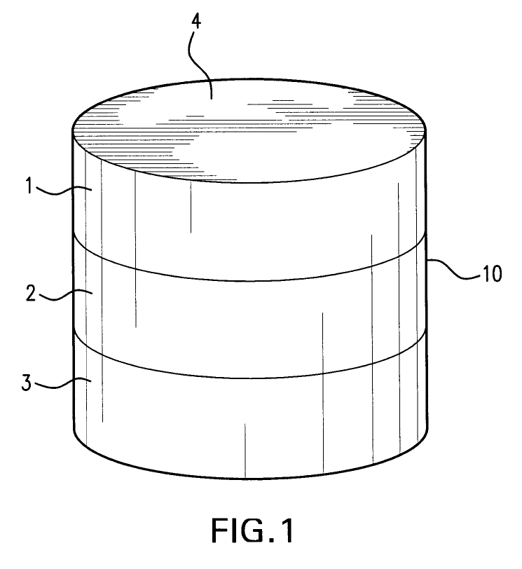

As indicated above, as used herein, “arranged vertically in descending order of their energy gaps with the first cell having the largest energy gap of the cells in the stack” means that the cells in the stack are arranged sequentially with the first cell having the largest energy gap, the second cell directly below the first cell having the next largest energy gap, the third cell directly below the second cell having the third largest energy gap, etc. This arrangement of a cell stack is shown schematically in FIG. 1. The cell stack 10 has three cells, 1, 2 and 3, with cell 1 being the first cell. The energy gaps of the three cells are such that E_{g}¹>E_{g}²>E_{g}³ where E_{g}¹ is the energy gap of cell 1, E_{g}² is the energy gap of cell 2 and E_{g}³ is the energy gap of cell 3. Cell 1 will absorb the light with photons of energy ≧E_{g}¹ and transmit the light with photons of energy <E_{g}¹. Cell 2 will absorb the light with photons of energy ≧E_{g}² and transmit the light with photons of energy <E_{g}². Similarly with cell 3. The cells convert the energy of the absorbed photons into electricity.

“Absorbed” as used herein means that a photon absorbed by the cell results in the creation of an electron-hole pair.

“The dichroic mirror operating at E_{g}^{m}” is used herein to mean that the dichroic mirror provides a separation of the light transmitted by the HEGC stack into two spectral components, one component of light with photons of energy ≧E_{g}^{m} and one component of light with photons of energy <E_{g}^{m}. One of these components is reflected by the dichroic mirror and one is transmitted by the dichroic mirror. A “cold” dichroic mirror reflects light with photons of energy ≧E_{g}^{m} and transmits light with photons of energy <E_{g}^{m} and a “hot” dichroic mirror transmits light with photons of energy ≧E_{g}^{m} and reflects light with photons of energy <E_{g}^{m}. Typically the dichroic mirror will be positioned so that it is not perpendicular to the light transmitted by the HEGC stack. In this way the direction of the reflected light is not directly back toward the HEGC stack but is rather at an angle with respect to the direction of the light impinging on the dichroic mirror and the reflected light can more readily be arranged to impinge upon other cells. The transition from transmission to reflection occurs over a range of energies and corresponding wavelengths. The operating energy E_{g}^{m} is taken as the midpoint of this transition region. Unless the transition is extremely sharp, it is recognized that some photons of energy ≧E_{g}^{m} will be transmitted and some photons of energy <E_{g}^{m} will be reflected. In the transition range, the majority of photons with energies greater than E_{g}^{m} are reflected; the majority of photons with energies less than E_{g}^{m} are transmitted. The above definition of “the dichroic mirror operating at E_{g}^{m}” should be understood and interpreted in terms of this recognition of the nature of the transition region. For a given dichroic mirror, the operating energy shifts to lower energies (higher wavelengths) as the dichroic mirror is rotated away from being perpendicular to the direction of incidence of the light beam impinging upon it and “the dichroic mirror operating at E_{g}^{m}” should be understood and interpreted to apply to the position in which the dichroic mirror is placed relative to the direction of the impinging light A dichroic mirror is a multilayer structure, typically containing 20 or more alternate layers of two transparent oxides. A sharper transition requires more layers and higher cost.

In one embodiment of the solar cell, the solar cell is comprised of a MEGC stack in addition to the HEGC stack and the dichroic mirror. The component of light with photons of energy ≧E_{g}^{m} is arranged to impinge upon the MEGC. This solar cell is herein referred to as a solar cell with the “HEGC stack-dichroic mirror-MEGC stack” architecture. The component of light with photons of energy <E_{g}^{m} is arranged to impinge upon other cells. For example, this light can be further split into spectral components before impinging on the other cells.

In another embodiment of the solar cell, the solar cell is comprised of a LEGC stack in addition to the HEGC stack and the dichroic mirror. The component of light with photons of energy <E_{g}^{m} is arranged to impinge upon the LEGC stack. This solar cell is herein referred to as a solar cell with the “HEGC stack-dichroic mirror-LEGC stack” architecture. The component of light with photons of energy ≧E_{g}^{m} is arranged to impinge upon other cells. For example, this light can be further split into spectral components before impinging on the other cells.

In an especially preferred embodiment of the solar cell, the solar cell is comprised of a MEGC stack and a LEGC stack in addition to the HEGC stack and the dichroic mirror. The component of light with photons of energy ≧E_{g}^{m} is arranged to impinge upon the MEGC stack and the component of light with photons of energy <E_{g}^{m} is arranged to impinge upon the LEGC stack. This solar cell is herein referred to as a solar cell with the “HEGC stack-dichroic mirror-MEGC stack-LEGC stack” architecture.

The MEGC stack contains one or more cells with different energy gaps arranged vertically in descending order of their energy gaps with the first cell having the largest energy gap of the one or more cells in the MEGC stack. The MEGC stack is positioned so that the component of light with photons of energy ≧E_{g}^{m} impinges upon the surface of the first cell in the MEGC stack. The energy gap of each cell in the MEGC stack is ≧E_{g}^{m} and <E_{g}^{h}. The one or more cells in the MEGC stack each absorb light with photons of energy greater than or equal to their energy gap and are transparent to and transmit light with photons of energy less than their energy gap. Preferably, the MEGC stack contains at least two cells.

The LEGC stack contains one or more cells with different energy gaps arranged vertically in descending order of their energy gaps with the first cell having the largest energy gap of the one or more cells in the LEGC stack. The LEGC stack is positioned so that the component of light with photons of energy <E_{g}^{m} impinges upon the surface of the first cell in the LEGC stack. The energy gap of each cell in the LEGC stack is <E_{g}^{m}. The one or more cells in the LEGC stack each absorb light with photons of energy greater than or equal to their energy gap and are transparent to and transmit light with photons of energy less than their energy gap. Preferably, the LEGC stack contains at least two cells. Preferably, the energy gap of the cell with the lowest energy gap is sufficiently low to effectively absorb the majority of photons transmitted to it.

The E_{g}^{m} at which the dichroic mirror is designed to operate is determined by the energy gaps of the specific cells being used. Preferably, E_{g}^{m} is about equal to the energy gap of the cell with the lowest energy gap of all the cells to which the component of light with photons of energy ≧E_{g}^{m} is directed. When there is a MEGC stack present, as in the “HEGC stack-dichroic mirror-MEGC stack” or “HEGC stack-dichroic mirror-MEGC stack-LEGC stack” architectures, preferably E_{g}^{m} is about equal to the energy gap of the cell with the lowest energy gap of the cells in the MEGC stack. If the component of light with photons of energy ≧E_{g}^{m} is further spectrally divided, E_{g}^{m} is about equal to the energy gap of the cell with the lowest energy gap of the cells impinged by the spatially divided light.

The light reflected and/or transmitted by the dichroic mirror can impinge directly upon the surface of the first cell in the appropriate stack. Alternatively, a reflecting mirror can be positioned so that light reflected and/or transmitted by the dichroic mirror is reflected by the reflecting mirror and directed to impinge upon the surface of the first cell in the appropriate stack, i.e., light with photons of energy ≧E_{g}^{m} is directed to impinge upon the surface of the first cell in the MEGC stack and light with photons of energy <E_{g}^{m} is directed to impinge upon the surface of the first cell in the LEGC stack

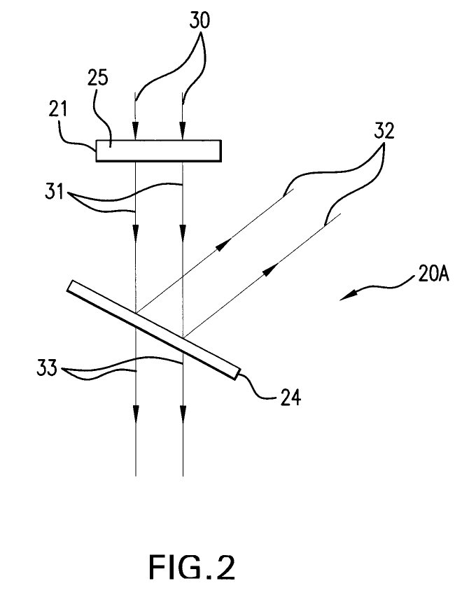

In FIGS. 2-7, the same numbers are used to identify the same entities. For, simplicity, the various light beams are represented by two light rays.

FIG. 2 illustrates an embodiment of the solar cell with the “HEGC stack-dichroic mirror” architecture. The solar cell 20A is comprised of HEGC stack 21 and “cold” dichroic mirror 24. The HEGC stack 21 as shown contains one cell 25 having an energy gap E_{g}^{h}. The dichroic mirror 24 operates at E_{g}^{m} and reflects light with photons of energy ≧E_{g}^{m} and transmits light with photons of energy <E_{g}^{m}. Solar light 30 impinges upon the surface of the high energy gap cell 25. High energy gap cell 25 absorbs light with photons of energy ≧E_{g}^{h} and transmits light 31 with photons of energy <E_{g}^{h}. The light 31 impinges upon the dichroic mirror 24 which is positioned so that it is not perpendicular to the direction of the light 31. Light 32 with photons of energy ≧E_{g}^{m} is reflected by the dichroic mirror. Light 33 with photons of energy <E_{g}^{m} is transmitted by the dichroic mirror.

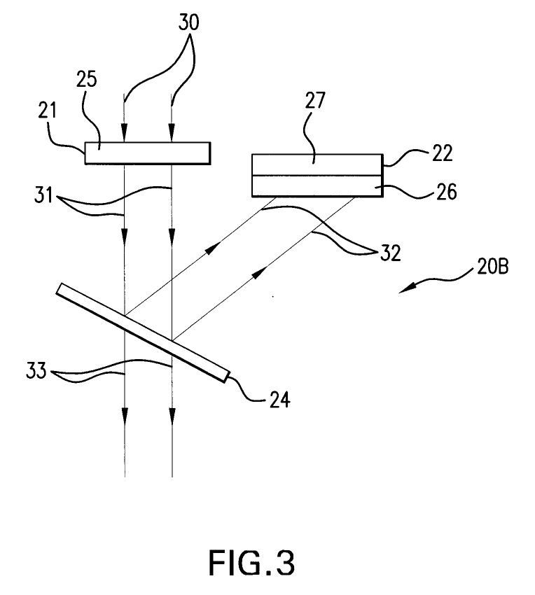

FIG. 3 illustrates an embodiment of the solar cell with the “HEGC stack-dichroic mirror-MEGC stack” architecture. The solar cell 20B is comprised of HEGC stack 21, MEGC stack 22 and “cold” dichroic mirror 24. The HEGC stack 21 as shown contains one cell 25 having an energy gap E_{g}^{h}. The MEGC stack 22 as shown contains two cells 26 and 27 with different energy gaps E_{g}²⁶ and E_{g}²⁷, where E_{g}²⁶ and E_{g}²⁷ are both ≧E_{g}^{m} and <E_{g}^{h} and E_{g}²⁶ is >E_{g}²⁷. The dichroic mirror 24 operates at E_{g}^{m} and reflects light with photons of energy ≧E_{g}^{m} and transmits light with photons of energy <E_{g}^{m}. Solar light 30 impinges upon the surface of the high energy gap cell 25. High energy gap cell 25 absorbs light with photons of energy ≧E_{g}^{h} and transmits light 31 with photons of energy <E_{g}^{h}. The light 31 impinges upon the dichroic mirror 24 which is positioned so that it is not perpendicular to the direction of the light 31. Light 32 with photons of energy ≧E_{g}^{m} is reflected by the dichroic mirror and impinges upon the surface of the first cell 26 of the MEGC stack 22. Cells 26 and 27 each absorb light with photons of energy greater than or equal to their energy gap and are transparent to and transmit light with photons of energy less than their energy gap. Light 33 with photons of energy <E_{g}^{m} is transmitted by the dichroic mirror.

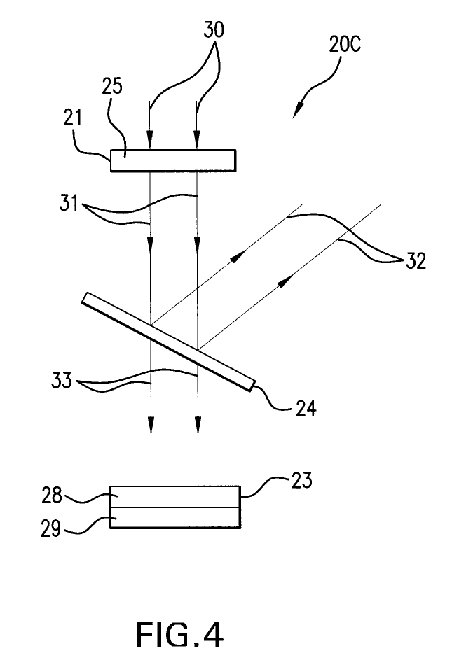

FIG. 4 illustrates an embodiment of the solar cell with the “HEGC stack-dichroic mirror-LEGC stack” architecture. The solar cell 20C is comprised of HEGC stack 21, LEGC stack 23 and “cold” dichroic mirror 24. The HEGC stack 21 as shown contains one cell 25 having an energy gap E_{g}^{h}. The LEGC stack 23 as shown contains two cells 28 and 29 with different energy gaps E_{g}²⁸ and E_{g}²⁹, where E_{g}²⁸ and E_{g}²⁹ are both <E_{g}^{m} and E_{g}²⁸ is >E_{g}²⁹. The dichroic mirror 24 operates at E_{g}^{m} and reflects light with photons of energy ≧E_{g}^{m} and transmits light with photons of energy <E_{g}^{m}. Solar light 30 impinges upon the surface of the high energy gap cell 25. High energy gap cell 25 absorbs light with photons of energy E_{g}^{h} and transmits light 31 with photons of energy <E_{g}^{h}. The light 31 impinges upon the dichroic mirror 24 which is positioned so that it is not perpendicular to the direction of the light 31. Light 32 with photons of energy ≧E_{g}^{m} is reflected by the dichroic mirror. Light 33 with photons of energy <E_{g}^{m} is transmitted by the dichroic mirror and impinges upon the surface of the first cell 28 of the LEGC stack 23. Cells 28 and 29 each absorb light with photons of energy greater than or equal to their energy gap and are transparent to and transmit light with photons of energy less than their energy gap.

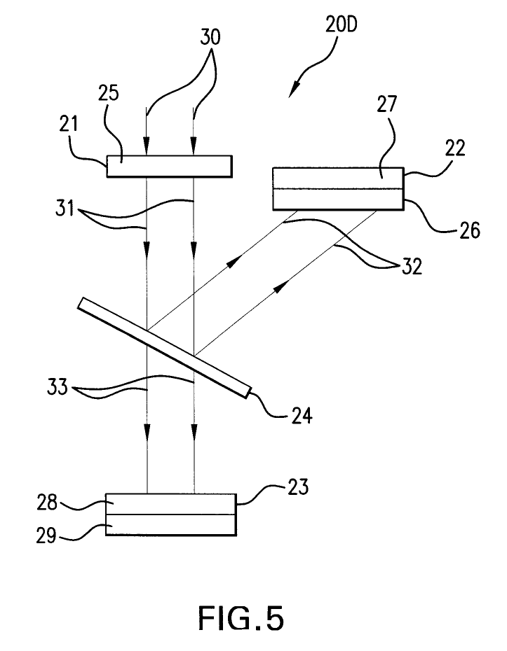

FIG. 5 illustrates an embodiment of the solar cell with the “HEGC stack-dichroic mirror-MEGC stack-LEGC stack” architecture. The solar cell 20D is comprised of HEGC stack 21, MEGC stack 22, LEGC stack 23 and “cold” dichroic mirror 24. The HEGC stack 21 as shown contains one cell 25 having an energy gap E_{g}^{h}. The MEGC stack 22 as shown contains two cells 26 and 27 with different energy gaps E_{g}²⁶ and E_{g}²⁷, where E_{g}²⁶ and E_{g}²⁷ are both ≧E_{g}^{m} and <E_{g}^{h} and E_{g}²⁶ is >E_{g}²⁷. The LEGC stack 23 as shown contains two cells 28 and 29 with different energy gaps E_{g}²⁸ and E_{g}²⁹, where E_{g}²⁸ and E_{g}²⁹ are both <E_{g}^{m} and E_{g}²⁸ is >E_{g}²⁹. The dichroic mirror 24 operates at E_{g}^{m} and reflects light with photons of energy ≧E_{g}^{m} and transmits light with photons of energy <E_{g}^{m}. Solar light 30 impinges upon the surface of the high energy gap cell 25. High energy gap cell 25 absorbs light with photons of energy ≧E_{g}^{h} and transmits light 31 with photons of energy <E_{g}^{h}. The light 31 impinges upon the dichroic mirror 24 which is positioned so that it is not perpendicular to the direction of the light 31. Light 32 with photons of energy ≧E_{g}^{m} is reflected by the dichroic mirror and impinges upon the surface of the first cell 26 of the MEGC stack 22. Cells 26 and 27 each absorb light with photons of energy greater than or equal to their energy gap and are transparent to and transmit light with photons of energy less than their energy gap. Light 33 with photons of energy <E_{g}^{m} is transmitted by the dichroic mirror and impinges upon the surface of the first cell 28 of the LEGC stack 23. Cells 28 and 29 each absorb light with photons of energy greater than or equal to their energy gap and are transparent to and transmit light with photons of energy less than their energy gap.

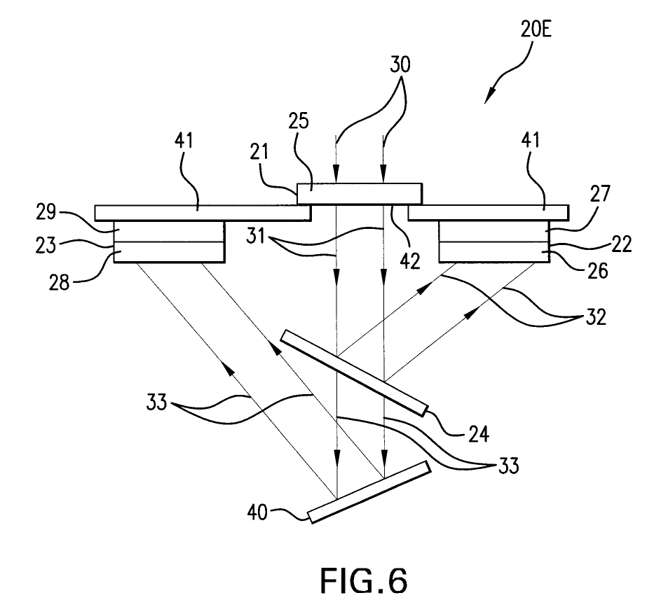

FIG. 6 illustrates another embodiment of the solar cell with the “HEGC stack-dichroic mirror-MEGC stack-LEGC stack” architecture in which the three stacks are mounted on a single mounting board. The solar cell 20E is comprised of HEGC stack 21, MEGC stack 22, LEGC stack 23, “cold” dichroic mirror 24, reflecting mirror 40 and a single mounting board 41. The HEGC stack 21 as shown contains one cell 25 having an energy gap E_{g}^{h}. The MEGC stack 22 as shown contains two cells 26 and 27 with different energy gaps E_{g}²⁶ and E_{g}²⁷, where E_{g}²⁶ and E_{g}²⁷ are both ≧E_{g}^{m} and <E_{g}^{h} and E_{g}²⁶ is >E_{g}²⁷. The LEGC stack 23 as shown contains two cells 28 and 29 with different energy gaps E_{g}²⁸ and E_{g}²⁹, where E_{g}²⁸ and E_{g}²⁹ are both <E_{g}^{m} and E_{g}²⁸ is >E_{g}²⁹. The dichroic mirror 24 operates at E_{g}^{m} and reflects light with photons of energy ≧E_{g}^{m} and transmits light with photons of energy <E_{g}^{m}. Solar light 30 impinges upon the surface of the high energy gap cell 25. High energy gap cell 25 absorbs light with photons of energy ≧E_{g}^{h} and transmits light 31 with photons of energy <E_{g}^{h}. The light 31 impinges upon the dichroic mirror 24 which is positioned so that it is not perpendicular to the direction of the light 31. Light 32 with photons of energy ≧E_{g}^{m} is reflected by the dichroic mirror and impinges upon the surface of the first cell 26 of the MEGC stack 22. Cells 26 and 27 each absorb light with photons of energy greater than or equal to their energy gap and are transparent to and transmit light with photons of energy less than their energy gap. Light 33 with photons of energy <E_{g}^{m} is transmitted by the dichroic mirror and is reflected by the reflecting mirror 40. The reflected light 33 impinges upon the surface of the first cell 28 of the LEGC stack 23. Cells 28 and 29 each absorb light with photons of energy greater than or equal to their energy gap and are transparent to and transmit light with photons of energy less than their energy gap. The HEGC, MEGC and LEGC stacks are all supported by mounting board 41. An opening 42 in the mounting board 41 is provided to allow for the transmission of light 31. Alternatively, a transparent material could fill the opening or a mounting board that is transparent to the light 31 could be used.

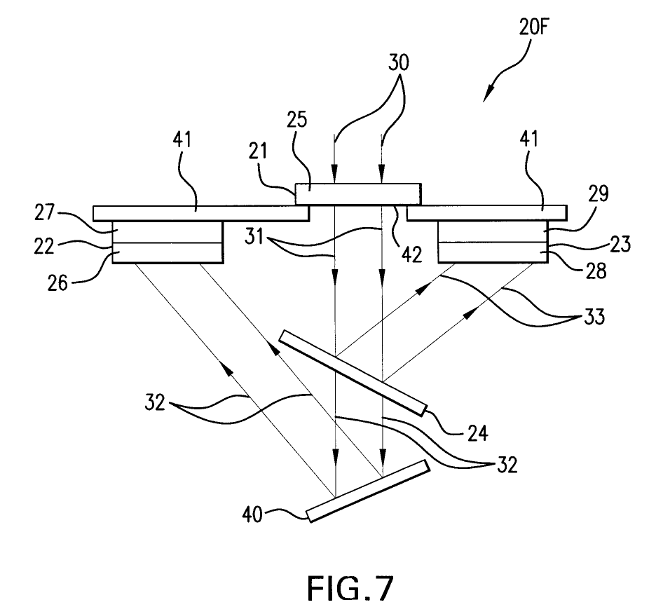

When a dichroic mirror is used that operates at E_{g}^{m} and reflects light with photons of energy <E_{g}^{m} and transmits light with photons of energy ≧E_{g}^{m}, the light 33 shown in FIGS. 2-6 with photons of energy <E_{g}^{m} is reflected by the dichroic mirror and light 32 with photons of energy ≧E_{g}^{m} is transmitted by the dichroic mirror. As a result a MEGC 22 is positioned where the LEGC stack 23 is shown in FIGS. 2-6 and a LEGC stack 23 is positioned where MEGC stack 22 is shown in FIGS. 2-6. This is clearly see by comparing FIGS. 6 and 7.

FIG. 7 illustrates another embodiment of the solar cell with the “HEGC stack-dichroic mirror-MEGC stack-LEGC stack” architecture in which the three stacks are mounted on a single mounting board. The solar cell 20F is comprised of HEGC stack 21, MEGC stack 22, LEGC stack 23, “hot” dichroic mirror 24, reflecting mirror 40 and a single mounting board 41. The HEGC stack 21 as shown contains one cell 25 having an energy gap E_{g}^{h}. The MEGC stack 22 as shown contains two cells 26 and 27 with different energy gaps E_{g}²⁶ and E_{g}²⁷, where E_{g}²⁶ and E_{g}²⁷ are both ≧E_{g}^{m} and <E_{g}^{h} and E_{g}²⁶ is >E_{g}²⁷. The LEGC stack 23 as shown contains two cells 28 and 29 with different energy gaps E_{g}²⁸ and E_{g}²⁹, where E_{g}²⁸ and E_{g}²⁹ are both <E_{g}^{m} and E_{g}²⁸ is >E_{g}²⁹. The dichroic mirror 24 operates at E_{g}^{m} and transmits light with photons of energy ≧E_{g}^{m} and reflects light with photons of energy <E_{g}^{m}. Solar light 30 impinges upon the surface of the high energy gap cell 25. High energy gap cell 25 absorbs light with photons of energy ≧E_{g}^{h} and transmits light 31 with photons of energy <E_{g}^{h}. The light 31 impinges upon the dichroic mirror 24 which is positioned so that it is not perpendicular to the direction of the light 31. Light 33 with photons of energy <E_{g}^{m} is reflected by the dichroic mirror and impinges upon the surface of the first cell 28 of the LEGC stack 23. Cells 28 and 29 each absorb light with photons of energy greater than or equal to their energy gap and are transparent to and transmit light with photons of energy less than their energy gap. Light 32 with photons of energy ≧E_{g}^{m} is transmitted by the dichroic mirror and is reflected by the reflecting mirror 40. The reflected light 32 impinges upon the surface of the first cell 26 of the MEGC stack 22. Cells 26 and 27 each absorb light with photons of energy greater than or equal to their energy gap and are transparent to and transmit light with photons of energy less than their energy gap. The HEGC, MEGC and LEGC stacks are all supported by mounting board 41. An opening 42 in the mounting board 41 is provided to allow for the transmission of light 31. Alternatively, a transparent material could fill the opening or a mounting board that is transparent to the light 31 could be used.

Materials suitable for cells for the HEGC stack with energy gaps ≧2.0 eV can be selected from the III-V GaInP/AlGaInP and AlInGaN material systems. An InGaN cell with an energy gap of 2.4 eV is a preferred cell. For preparation see, for example, O. Jani et al., Conference Record, 2006 IEEE 4^{th} World Conference on Photovoltaic Energy Conversion, May 10, 2006, Waikoloa, Hi. When the HEGC stack contains only one cell, InGaN on a sapphire substrate is preferred. The InGaN-sapphire combination has a low index of refraction with that of the InGaN of about 2.1-2.3 and that of sapphire of about 1.8. This reduces the requirements on the optical anti-reflection coatings used to minimize the reflection of solar light from the cell surface. The sapphire substrate could be shaped to serve as a lens.

Materials suitable for cells for the MEGC stack with energy gaps <2.0 eV and ≧E_{g}^{m} where E_{g}^{m} is about 1.4 eV can be selected from the III-V GaInP/GaAsP/GaInAs material system. A GaInP cell with an energy gap of 1.84 eV and a GaAs cell with an energy gap of 1.43 eV are two of the preferred cells for the MEGC stack. A two cell MEGC stack consisting of GaInP/GaAs tandem cells can be prepared using, trimethyl gallium, trimethyl indium, phosphine, arsine and other precursors as described by K. A. Bertness et al., Appl. Phys. Lett. 65, 989 (1994).

GaAs is a preferred cell for the cell with the lowest energy gap in a MEGC stack. It is also a preferred cell to be used as the cell with the lowest energy gap when the component of light with photons of energy ≧E_{g}^{m} is further spectrally divided. Therefore, it is preferred for E_{g}^{m} to be about 1.43 eV

Cells with energy gaps <E_{g}^{m}, where E_{g}^{m} is about 1.4 eV, suitable for use in the LEGC stack are silicon cells with an energy gap of 1.12 eV and InGaAs and InGaAsP cells with energy gaps <1 eV. Silicon cells and their preparation are well-known. The InGaAs cells are state of the art devices designed for thermophotovoltaic applications. For preparation see, for example, R. J. Wehrer et al., Conference Record, IEEE Photovoltaic Specialists Conference, 2002, p 884-887.

In one embodiment, the cells in one or more stacks can be electrically connected in series to provide a single output for the stack. In a more preferred embodiment, all the individual cells in the HEGC, MEGC and LEGC stacks are contacted with individual electrical connections. This results in a substantial simplification of the solar cell and provides the opportunity to regulate the voltage across each cell at a value to provide optimum operation of the cell. The cells can be connected to a power combiner that provides a single electrical output for the solar cell at the desired voltage.

The HEGC, MEGC and LEGC stacks can be mounted on one or more mounting boards depending on the configuration of the particular embodiment. The mounting board can be in the form of a silicon cell that would serve as a scavenger cell to absorb light not otherwise absorbed and convert it into electricity.

Light reflected from the surfaces of cells is a potential source of decreased solar cell efficiency. An anti-reflection coating can be applied to the surfaces of any of the cells upon which light impinges to minimize this loss.

In one embodiment the light transmitted by the HEGC stack and the light reflected and transmitted by the dichroic mirror propagates in air before impinging on the dichroic mirror and on the respective cells or stacks. In another embodiment one or more transparent solids can be provided for these various lights to propagate through.

In a preferred embodiment, the high efficiency solar cell further comprises an optical element. The intensity or concentration of solar radiation striking a surface is 1×, the normal concentration. It is more difficult and more expensive to achieve high solar cell efficiency with 1× solar light than it is using solar light of higher concentrations. The purpose of the optical element is to collect and concentrate the light impinging upon it and direct the light upon the surface of the first cell in the HEGC stack. The optical element comprises a total internal reflecting concentrator that is a static concentrator. This static concentrator increases the power density of the solar light that can be utilized by the solar cell. It is a wide acceptance-angle concentrator that accepts light from a large portion of the sky. Unlike a tracking concentrator, the static concentrator is able to capture most of the diffuse light, much of which is in the blue to ultraviolet portion of the spectrum. This diffuse light makes up about 10% of the incident power in the solar spectrum. In practice, high levels of concentration are achieved by rejecting light from those portions of the sky in which the power density of the solar radiation is low throughout the year. In this way, concentrations of the solar light are increased by a factor of 10×. Higher concentrations are obtained if the position of the concentrator can be adjusted at some time during the year. Light is transmitted through one surface of the concentrator and that surface is adjacent to the surface of the first cell in the HEGC stack. “Solar light” is used herein to refer to the complete solar spectrum that impinges upon the surface of the first cell in the HEGC stack, no matter what the concentration. Preferably, the concentration is 10× or higher.

What is claimed is:

1. A high efficiency solar cell, comprising a high energy gap cell (HEGC) stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h}, wherein the one or more cells in the HEGC stack each absorb light with photons of energy greater than or equal to their energy gap and are transparent to and transmit light with photons of energy less than their energy gap thereby providing light transmitted by the HEGC stack and wherein E_{g}^{h}≧2.0 eV.

2. The high efficiency solar cell of claim 1, further comprising one or more spectral beam splitters upon which the light transmitted by the HEGC stack impinges, wherein the one or more spectral beam splitters split the light transmitted by the HEGC stack into two or more spectral components.

3. A high efficiency solar cell, comprising:
(a) a high energy gap cell (HEGC) stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack; and
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy ≧E_{g}^{m} and one component of light with photons of energy <E_{g}^{m} and wherein one of these components is reflected by the dichroic mirror and one is transmitted by the dichroic mirror.

4. The high efficiency solar cell of claim 3, wherein the dichroic mirror reflects light with photons of energy ≧E_{g}^{m} and transmits light with photons of energy <E_{g}^{m}.

5. The high efficiency solar cell of claim 3, wherein E_{g}^{h}≧2.0 eV and E_{g}^{m} is about equal to the energy gap of the cell with the lowest energy gap of all the cells to which the component of light with photons of energy ≧E_{g}^{m} is directed.

6. The high efficiency solar cell of claim 5, wherein the cell with the lowest energy gap is a GaAs cell and E g^{m} is about 1.43 eV.

7. The high efficiency solar cell of claim 3, further comprising:
(c) a mid energy gap cell (MEGC) stack that contains one or more cells with different energy gaps arranged vertically in descending order of their energy gaps with the first cell having the largest energy gap of the one or more cells in the MEGC stack, the MEGC stack being positioned so that the component of light with photons of energy ≧E_{g}^{m} impinges upon the surface of the first cell in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap.

8. The high efficiency solar cell of claim 1, further comprising:
(c) a low energy gap cell (LEGC) stack that contains one or more cells with different energy gaps arranged vertically in descending order of their energy gaps with the first cell having the largest energy gap of the one or more cells in the LEGC stack, the LEGC stack being positioned so that the component of light with photons of energy <E_{g}^{m} impinges upon the surface of the first cell in the LEGC stack, wherein the energy gap of each cell in the LEGC stack is <E_{g}^{m} and wherein the one or more cells in the LEGC stack each absorb light with photons of energy greater than or equal to their energy gap and are transparent to and transmit light with photons of energy less than their energy gap.

9. A high efficiency solar cell, comprising:
(a) a high energy gap cell (HEGC) stack that contains one or more cells with different energy gaps arranged vertically in descending order of their energy gaps with the first cell having the largest energy gap of the one or more cells in the HEGC stack, wherein solar light impinges upon the surface of the first cell in the HEGC stack before there is any splitting of the solar light into spectral components, wherein the energy gap of each cell in the HEGC stack is ≧E_{g}^{h} and wherein the one or more cells in the HEGC stack each absorb light with photons of energy greater than or equal to their energy gap and are transparent to and transmit light with photons of energy less than their energy gap thereby providing light transmitted by the HEGC stack;
(b) a dichroic mirror operating at E_{g}^{m} and positioned so that the light transmitted by the HEGC stack impinges upon the dichroic mirror, wherein E_{g}^{m}<E_{g}^{h} and wherein the dichroic mirror provides a separation of the light transmitted by the HEGC stack into two spectral components, one component of light with photons of energy ≧E_{g}^{m} and one component of light with photons of energy <E_{g}^{m} and wherein one of these components is reflected by the dichroic mirror and one is transmitted by the dichroic mirror;
(c) a mid energy gap cell (MEGC) stack that contains one or more cells with different energy gaps arranged vertically in descending order of their energy gaps with the first cell having the largest energy gap of the one or more cells in the MEGC stack, the MEGC stack being positioned so that the component of light with photons of energy ≧E_{g}^{m} impinges upon the surface of the first cell in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap; and
(d) a low energy gap cell (LEGC) stack that contains one or more cells with different energy gaps arranged vertically in descending order of their energy gaps with the first cell having the largest energy gap of the one or more cells in the LEGC stack, the LEGC stack being positioned so that the component of light with photons of energy <E_{g}^{m} impinges upon the surface of the first cell in the LEGC stack, wherein the energy gap of each cell in the LEGC stack is <E_{g}^{m} and wherein the one or more cells in the LEGC stack each absorb light with photons of energy greater than or equal to their energy gap and are transparent to and transmit light with photons of energy less than their energy gap.

10. The high efficiency solar cell of claim 9, wherein the dichroic mirror reflects light with photons of energy ≧E_{g}^{m} and transmits light with photons of energy <E_{g}^{m}, the MEGC stack being positioned so that the reflected light with photons of energy ≧E_{g}^{m} impinges upon the surface of the first cell in the MEGC stack and the LEGC stack being positioned so that the transmitted light with photons of energy <E_{g}^{m} impinges upon the surface of the first cell in the LEGC stack.

11. The high efficiency solar cell of claim 9, wherein E_{g}^{h}≧2.0 eV and E_{g}^{m} is about equal to the energy gap of the cell with the lowest energy gap in the MEGC stack.

12. The high efficiency solar cell of claim 11, wherein the cell with the lowest energy gap is a GaAs cell and E_{g}^{m} is about 1.43 eV.

13. The high efficiency solar cell of claim 9, wherein the HEGC stack contains one cell, the MEGC stack contains at least two cells and the LEGC stack contains at least two cells.

14. The high efficiency solar cell of claim 10, wherein E_{g}^{h}≧2.0 eV and E_{g}^{m} is about equal to the energy gap of the cell with the lowest energy gap in the MEGC stack.

15. The high efficiency solar cell of claim 14, wherein the cell with the lowest energy gap is a GaAs cell and E_{g}^{m} is about 1.43 eV.

16. The high efficiency solar cell of claim 10, wherein the HEGC stack contains one cell, the MEGC stack contains at least two cells and the LEGC stack contains at least two cells.

17. The high efficiency solar cell of claim 9, wherein all the individual cells in the HEGC, MEGC and LEGC stacks are contacted with individual electrical connections.

18. The high efficiency solar cell of claim 9, further comprising a reflecting mirror positioned so that light transmitted by the dichroic mirror is reflected by the reflecting mirror and directed to impinge upon the surface of the first cell in the appropriate stack.

19. The high efficiency solar cell of claim 9, further comprising an optical element to collect and concentrate the solar light and direct the concentrated solar light to impinge upon the surface of the first cell in the HEGC stack.

20. A method for converting solar light into electrical power, the method comprising:
(a) positioning a high energy gap cell (HEGC) stack so that solar light impinges onto the surface of the first cell of the HEGC stack before there is any splitting of the solar light into spectral components, wherein the HEGC stack contains one or more cells with different energy gaps arranged vertically in descending order of their energy gaps with the first cell having the largest energy gap of the one or more cells in the HEGC stack, wherein the energy gap of each cell in the HEGC stack is ≧E_{g}^{h}, and wherein the one or more cells in the HEGC stack each absorb light with photons of energy greater than or equal to their energy gap and are transparent to and transmit light with photons of energy less than their energy gap thereby providing light transmitted by the HEGC stack;
(b) spatially separating the light transmitted by the HEGC stack into two spectral components of light, one component of light with photons of energy ≧E_{g}^{m} and one component of light with photons of energy <E_{g}^{m};
(c) positioning a mid energy gap cell (MEGC) stack so that the component of light with photons of energy ≧E_{g}^{m} impinges upon the surface of the first cell in the MEGC stack, wherein the MEGC stack contains one or more cells with different energy gaps arranged vertically in descending order of their energy gaps with the first cell having the largest energy gap of the one or more cells in the MEGC stack, wherein the energy gap of each cell in the MEGC stack is ≧E_{g}^{m} and <E_{g}^{h} and wherein the one or more cells in the MEGC stack each absorb light with photons of energy greater than or equal to their energy gap and are transparent to and transmit light with photons of energy less than their energy gap; and
(d) positioning a low energy gap cell (LEGC) stack so that the component of light with photons of energy <E_{g}^{m} impinges upon the surface of the first cell in the LEGC stack, wherein the LEGC stack contains one or more cells with different energy gaps arranged vertically in descending order of their energy gaps with the first cell having the largest energy gap of the one or more cells cells in the LEGC stack, and wherein the one or more cells in the LEGC stack each absorb light with photons of energy greater than or equal to their energy gap and are transparent to and transmit light with photons of energy less than their energy gap.

21. The method of claim 20, wherein E_{g}^{h}≧2.0 eV and E_{g}^{m} is about equal to the energy gap of the cell with the lowest energy gap in the MEGC stack.

22. The method of claim 21, wherein the cell with the lowest energy gap is a GaAs cell and E_{g}^{m} is about 1.43 eV.
